(19) United States
(12) Patent Application Publication
(10) Pub. No.: US 2018/0097527 A1
(43) Pub. Date: Apr. 5, 2018

(54) 32-BIT HDR PIXEL FORMAT WITH OPTIMUM PRECISION

(71) Applicant: Microsoft Technology Licensing, LLC, Redmond, WA (US)

(72) Inventors: Charles N. Boyd, Woodinville, WA (US); James D. Stanard, Redmond, WA (US)

(21) Appl. No.: 15/633,637

(22) Filed: Jun. 26, 2017

Related U.S. Application Data
(60) Provisional application No. 62/403,647, filed on Oct. 3, 2016.

(51) Int. Cl. H03M 7/24; H04N 1/407; G06F 3/14; G06T 5/50; H04N 19/36

(52) U.S. Cl. CPC H03M 7/24; H04N 1/407; H04N 1/6027; G06T 5/50; H04N 19/36; G06F 3/1423

(57) ABSTRACT

Methods, systems, and devices are described herein for encoding, decoding, and otherwise processing in hardware and/or software a high dynamic range (HDR) color data structure. In one example, a method for encoding pixel data may include receiving pixel data comprising a red, green, and blue (RGB) value. The method may further include transforming the received pixel data to an intermediate color space data, such as transformed CIE AYB space data. The method may further include compressing the intermediate color space data into less than 64 bits, such as 32 bits. In some aspects, the 32 bits may be divided into luminance information and chrominance information, including, for example, 14 bits representing a floating point luminance value, and 9 bits each representing two fixed point chrominance channel values.

### CROSS REFERENCE TO RELATED APPLICATIONS

This application claims benefit under 35 U.S.C. § 119(e) of Provisional U.S. patent application No. 62/403,647, filed Oct. 3, 2016, the contents of which is incorporated herein by reference in its entirety.

### TECHNICAL FIELD

This disclosure relates generally to high dynamic range digital images, and more particularly to encoding and transforming high dynamic range digital images.

### BACKGROUND

With the advent of physically-based rendering and high dynamic range (HDR) displays, computer generated image quality is being pushed to new levels. This new level of fidelity requires both a wide range and high precision for rendered pixels: a floating point format. The standard of real-time HDR formats currently is four 16-bit float values to represent color information in each pixel of an image, i.e., 64 bit HDR. 64-bit HDR formats use significant amounts of memory and bandwidth, and are not particularly suited for power-constrained devices. Console game developers and others have found that to obtain the most performance from rendering pipelines, trade-offs must be made with image quality in order to reduce the bandwidth and memory needs of render targets. The only 32-bit HDR format currently available for both reading and writing on modern GPUs is R11G11B10. This is a 3-channel color format, including a floating point number for each color value (RGB) with a 5-bit exponent. This represents the same range as float 16 but with about half of the precision (6 bits for red and green, 5 bits for blue vs. 10 bits for float 16). As a result, existing 32-bit HDR formats are imprecise. Accordingly, improvements can be made to HDR image formats.

### SUMMARY

Illustrative examples of the disclosure include, without limitation, methods, systems, and various devices. In one aspect methods, systems, and devices are described herein for encoding, decoding, and otherwise processing in hardware and/or software a high dynamic range (HDR) color data structure. In one example, a method for encoding pixel data may include receiving pixel data comprising a red, green, and blue (RGB) value. The method may further include transforming the received pixel data to an intermediate color space data, such as transformed CIE AYB space data. The method may further include compressing the intermediate color space data into less than 64 bits, such as 32 bits. In some aspects, the 32 bits may be divided into luminance information and chrominance information, including, for example, 14 bits representing a floating point luminance value, and 9 bits each representing two fixed point chrominance channel values.

In another example, a method for decoding color data may include unpacking LUV color data to intermediate color space data, wherein the unpacking includes performing at least one non-linear operation. The method may further include transforming the intermediate color space data into RGB color values, and outputting the RGB color values, for example, for storage, rendering, or one or more color modification operations. Other features of the systems and methods are described below.

The features, functions, and advantages can be achieved independently in various examples or may be combined in yet other examples, further details of which can be seen with reference to the following description and drawings.

### BRIEF DESCRIPTION OF THE DRAWINGS

Embodiments of the present disclosure will be described more fully hereinafter with reference to the accompanying drawings, in which:

FIG. 1 depicts an example computing system for displaying images or video.

FIG. 2 depicts an example graphics pipeline that may be implemented by a graphics processing unit.

FIG. 3 depicts the chromaticity diagram of CIELUV color space.

FIG. 4 depicts an example 32-bit HDR pixel data structure.

FIG. 5 depicts a u′ v′ color representation.

FIGS. 6A, 6B, 6C, 6D and 6E depict graphs comparing precision or max error of related numerical encodings.

FIG. 7 depicts an example process for encoding pixel data using a 32-bit HDR format.

FIG. 8 depicts an example process for decoding pixel data using a 32-bit HDR format.

FIG. 9 depicts an example general purpose computing environment in which the techniques described herein may be embodied.

### DETAILED DESCRIPTION OF ILLUSTRATIVE EMBODIMENTS

Systems and techniques are described herein for encoding, decoding, and otherwise processing in hardware and/or software an HDR color data structure. In one example, the HDR color data structure or format may include 32 bits of color information for each pixel in an image. The 32 bits may be divided into luminance information, and chrominance information. In one specific example, 14 bits may represent a luminance value, and 9 bits may each represent two chrominance channel values, such as u′ and v′. In some cases, the luminance value may be a floating point number, with 9 bits representing a floating point value, and 5 bits representing the exponent. In some cases, each of the chrominance values may be unorm values, or fixes decimal point numbers normalized to a range of values between 0 and 1.

In some cases, encoding the color data, such as RGB data, into this custom format may include transforming RGB data to an intermediate color space. From the intermediate color space, such as AYB space, the color data may then be compressed or converted to LUV color values, for example, represented in 32 bits. Decoding the 32 bit HDR color data structure may be the inverse of the encoding process. In some cases, one or more steps of the encoding and/or decoding process may be performed in hardware (e.g., hard coded), to enable manipulation of the color information while it is still being processed in a GPU. In some cases, the intermediate color space may be a linear color space allowing for linear mathematical operations such as color blending to be correctly performed. However, the LUV color space data may not have a linear relationship with an RGB color space or the intermediate color space, and so may not be readily combinable or modifiable via pixel or image processing. In view of this limitation, the compressed data structure may be partially decoded, for example, by hardware, to the intermediate color space to enable various image or pixel processing operations to be performed on the data, without having to send the data out of a rendering pipeline.

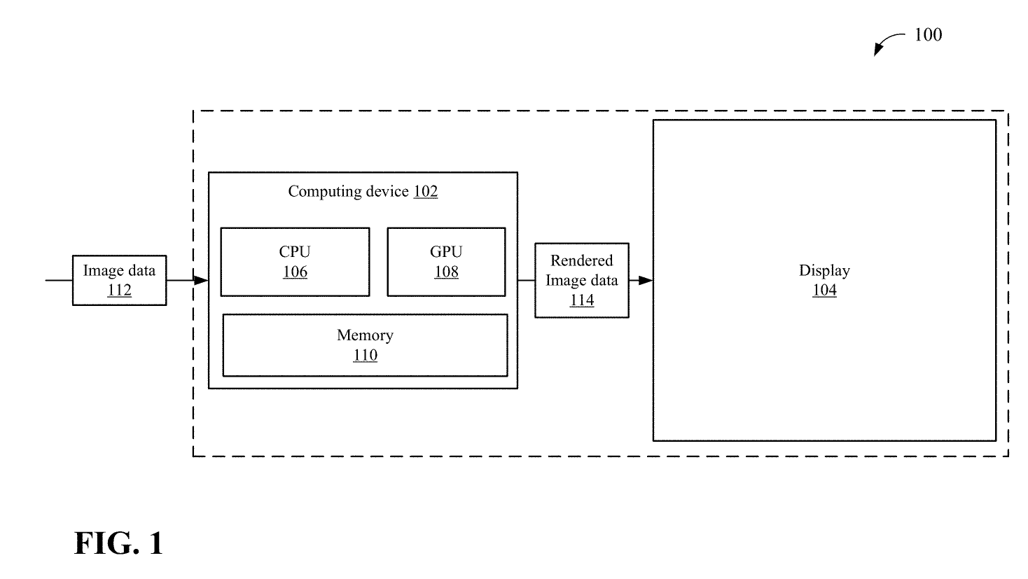

FIG. 1 depicts an example computing system 100 for displaying images or video. System 100 may include a computing device 102 and a display 104, which may be part of one unified computing device, such as a desktop computer, laptop, smart phone, tablet, etc., or a distributed computing system, in which one or more components of the system 100 may communicate over one or more networks. The computing device 102 may include at least a central processing unit (CPU) 106, a GPU graphics processing unit (GPU) 108, and memory 110, all in communication with each other.

In some aspects, GPU 108 may be partially or fully integrated with CPU 106, or may be a distinct and separate physical component from CPU 106 (e.g., on a video card, or embedded on the motherboard, etc.). GPU 108 may be a specialized electronic circuit designed to rapidly manipulate and alter memory to accelerate the creation of images in a frame buffer intended for output to a display. GPU 108 may have a highly parallel structure that enables the processing of large blocks of data in parallel. GPU 108 may be particularly useful for performing calculations associated with 3D graphics, including one or more of shading, transforming, clipping, lighting, blending, filtering, encoding, decoding, scan out, etc. In some aspects, one or more of these calculations or operations may be performed by software that interfaces with GPU, such as executed on CPU 106. In some aspects, GPU 108 may be a processing unit that facilitates graphics rendering. GPU 108 can be used to process vast amount of data-parallel computations efficiently. GPU 108 can be used to render images, glyphs, animations and video for display on a display screen 104 of a computing device 100. In some aspects, a GPU 108 (e.g., on a video card) can include hardware memory or access hardware memory. In some implementations, a memory unit(s) 110 that functions as both system memory (e.g., used by the CPU 106) and video memory (e.g., used by the GPU 108) can be employed. In other aspects, a memory unit that functions as system memory (e.g., used by the CPU 106) is separate from a memory unit that functions as video memory (e.g., used by the GPU 108). As can be appreciated, in some cases, the functionality of the GPU 108 may be emulated by the CPU 106.

To implement a graphics pipeline, one or more shaders on the GPU 108 may be utilized. Shaders may be considered as specialized processing subunits or programs of the GPU 108 for performing specialized operations on graphics data. Examples of shaders include a vertex shader, pixel shaders, and geometry shaders. Vertex shaders generally operate on vertices, and can apply computations of positions, colors, and texturing coordinates to individual vertices. For example, a vertex shader may perform either fixed or programmable function computations on streams of vertices specified in the memory of the graphics pipeline. Another example of a shader is a pixel shader. In one example, the outputs of a vertex shader can be passed to a pixel shader, which in turn operates on an individual pixel. Yet another type of shader includes a geometry shader. A geometry shader, which is typically executed after vertex shaders, can be used to generate new graphics primitives, such as points, lines, and triangles, from those primitives that were sent to the beginning of the graphics pipeline.

Operations performed by shaders typically read and/or write one or more external graphics-specific resources. Some examples of these resources include color buffers, depth buffers, and arbitrary data buffers. Resources are assigned positions in graphics memory. After a shader concludes its operations, the information may be placed in a GPU buffer. The information may be presented on an attached display device 104 or may be sent back to the host computing system 102 for further operations.

The GPU buffer provides a storage location on the GPU 108 where information, such as image, application, or other resources information, may be stored. As various processing operations are performed with respect to resources, the resources may be accessed from the GPU buffer, altered, and then re-stored on the buffer. The GPU buffer allows the resources being processed to remain on the GPU 108 while it is transformed by a graphics or compute pipeline. As it is time-consuming to transfer resources from the GPU 108 to the memory 110, it may be preferable for resources to remain on the GPU buffer until processing operations are completed.

GPU buffer also provides a location on the GPU 108 where graphics specific resources may be positioned. For example, a resource may be specified as having a certain-sized block of memory with a particular format (such as pixel format) and having specific parameters. In order for a shader to use the resource, it is bound to a “slot” in the graphics pipeline. By way of analogy and not limitation, a slot may be considered like a handle for accessing a particular resource in memory. Thus, memory from the slot can be accessed by specifying a slot number and a location within that resource.

In one example, computing system 100 may receive image data 112, which may be encoded using any of a variety of formats, include various amounts of data, etc. The computing device 102, and more specifically, the GPU 108, may perform one or more operations on the image data 112, and then transform the image data 12 and render it as image data 114 in a format displayable by display 104. The process of transforming the image data 112 into rendered image data 114 may be referred to herein as a graphics or rendering pipeline.

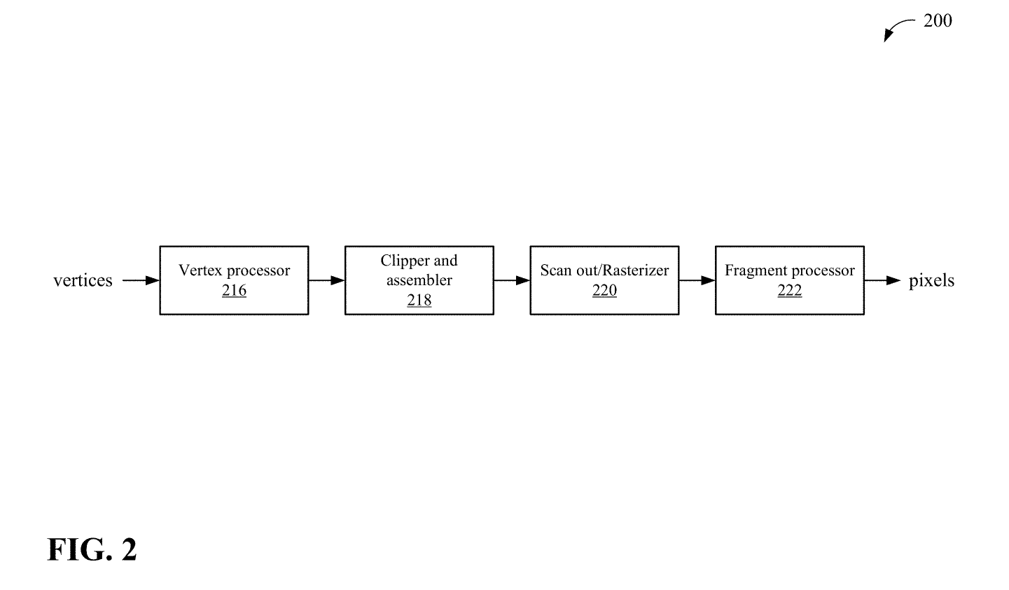

FIG. 2 depicts an example graphics pipeline 200, which may be implemented by a graphics processing unit, such as GPU 108. The example pipeline 200 is only described from a high level to provide a basis for the discussion of processing of a custom encoding for color data, which may be performed or relevant to the scan out and fragment processor stages, as will be described below. The graphics pipeline is well suited to the rendering process because it allows the GPU to function as a stream processor since all vertices and fragments can be thought of as independent. This allows multiple stages of the pipeline to be used simultaneously for different vertices or fragments as they work their way through the pipe. In addition to pipelining vertices and fragments, their independence allows graphics processors to use parallel processing units to process multiple vertices or fragments in a single stage of the pipeline at the same time.

In one example, graphics pipeline 200 may be mapped onto integrated graphics acceleration hardware of a GPU such that the input to the GPU is in the form of vertices. These vertices may undergo transformation and/or per-vertex lighting, via vertex processor 216. At this point in the pipeline, a custom vertex shader program can be used to manipulate the 3D vertices prior to rasterization. Once transformed and lit, the vertices undergo clipping, via clipper 218, and rasterization resulting in fragments, via scan out 220. A second custom shader program can then be run on each fragment, via fragment processor 222 before the final pixel values are output to the frame buffer for display. Fragment processor/custom shader 222 may be modified to perform various functions on the HDR color data structure described herein, such as reading writing, blending, filtering texturing, etc.

The described HDR format or color data structure may be utilized by various processes or operations in graphics or rendering pipeline 200. The HDR color data structure may represent color information in a non-linear space, such that in the fully compressed format, the color information may not be combinable with other color information and otherwise may not be transformable (filtered, blended, shaded, etc.). The HDR color data structure may be partially un-compressed or decoded into a linear representation of color or linear color space, such that it may be operated on by various graphic processes, without requiring full decoding.

In some aspects, this partial decoding operation may be performed by the GPU itself/hardware within the GPU to enable linearly correct blending and filtering of color values within the fixed function alpha blending and texture sampling units. Details of the exact transformation to the described HDR color format will be described below.

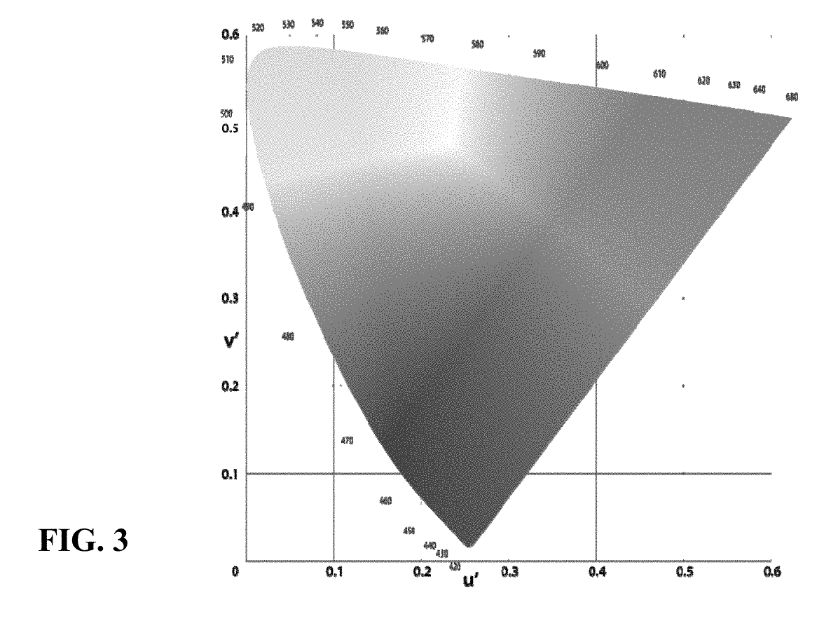

FIG. 3 depicts the chromaticity diagram of the CIELUV color space 300, which contains the entire color spectrum perceivable by the human visual system. CIELUV is a color representation different from, but related to, various RGB color spaces, as is known in the art. For example, to convert from a RGB color space to AYB space a 3×3 matrix multiplication is required. To convert from AYB space to the described format, another transformation or compression is needed, as will be described in greater detail below.

One way to encode or represent HDR colors is to separate luminance from chrominance. In some aspects, only luminance needs to be encoded with high dynamic range (i.e., a float number.) The LogLuv format does this very trick by transforming the color to AYB then computing:

u′=4A/(A+15Y+3B); and

v′=9Y/(A+15Y+3B).

Stopping there, [Y, u′, v′] forms the color space LUV, as illustrated in FIG. 3.

u′ and v′, in the LUV color space may be presented by values ranging from 0.0 to 1.0, but all of the colors perceivable by humans exist in the range 0.0 to 0.62. Based on this relationship, u′ and v′ values can be divided by 0.62 to maximize coverage of the unorm space, e.g., yield the most values, and hence, the most precision, with a uniform distribution. A uniform distribution of color values may provide the most perceivable difference with the range of values given, hence, it is desirable. Luminance, or Y in the AYB color space, is a floating point number with all of the range that provides. LogLuv actually takes Y and encodes log₂ Y as a fixed-point number, to break it up into two 8-bit pieces (technically S7.8) and to write the entire color to R8G8B8A8_UNORM.

Via experimentation, it has been determined that 16 bits for chroma or chrominance values, or u and v, is almost sufficient to express the range of perceivable colors. However, gradients using 8 bits for each U and V can be devised which demonstrate banding. Two 9-bit unorms, on the other hand, have been determined to have sufficient precision (double that of 8-bit unorms) to make color deltas small enough to be practically imperceptible. This is made possible because there is no correlation between luminance and chrominance and also because CIELUV was designed to distribute colors in a perceptually uniform way. Traditional YCC encodings like YPbPr do not decouple chrominance from luminance, and hence need just as much precision in all three channels. The use of log₂ ( ) is unnecessary as well since a float is already a logarithmic encoding for the exponent part. The last piece to this puzzle is that a sign bit is not needed, so a full float 16 already wastes one bit. In addition, if the least significant bit of the mantissa is rounded off, only 14 bits are needed to represent luminance, 9e5 or float 14 with as much range as float 16 and nearly as much precision. Coupled with two 9-bit unorm channels, that makes 32 bits.

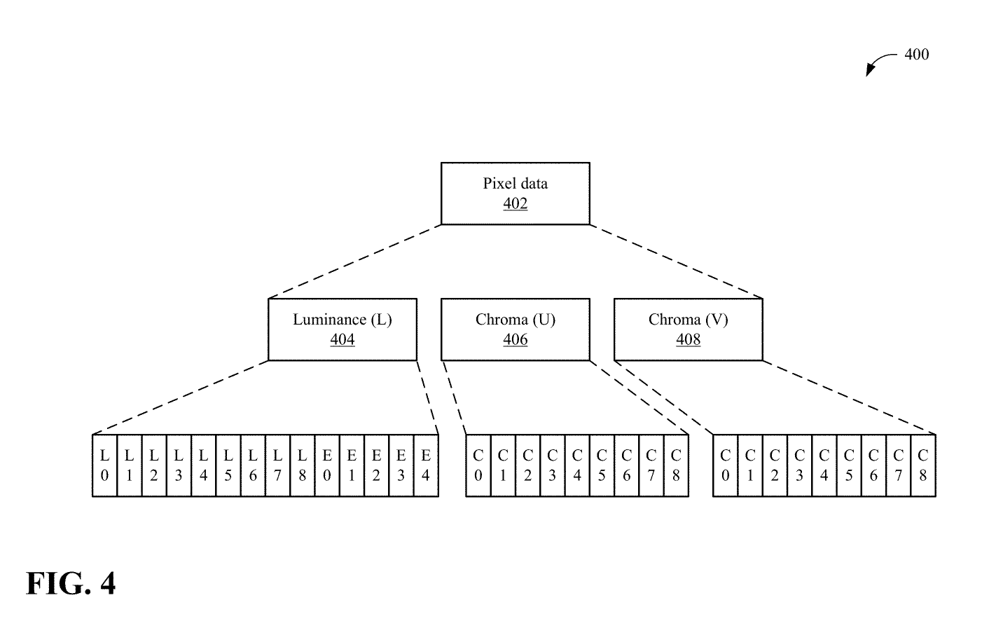

An example of the above-described color format is illustrated in FIG. 4. As used herein, this format or data structure for representing color of a pixel may be referred to as L14U9V9, LUV32, or a 32 bit HDR format. Data structure 400 may include pixel data 402, which may include space or allocations for luminance information 404, and chroma information, via channels 406 and 408, which may correspond to U and V color information. In one example, luminance information 404 may be allocated 14 bits, L0-L8, with 5 bits representing the exponent E0-E4). Luminance information 404 may be a floating point value, such that the decimal place may not be fixed in the representative 14 bits. The decimal point may be fixed at the start of the mantissa (following an implicit 1) and the resultant value may be multiplied by a magnitude or scale factor, which shifts the decimal point around (e.g., Value=(2.0**Exponent)* (1.Mantissa)). In some cases, the luminance value may be rounded from a 10 bit value, such that the least significant bit is discarded and L9 rounded based on the dropped least significant bit. In some cases, a sign value, either plus or minus, may also be discarded from the luminance value 404, as luminance can be assumed to also be a non-negative number. In this way, 14 bits may be used to represent a value that was previously represented by 16 bits, with only a slight degradation in precision (the least significant bit).

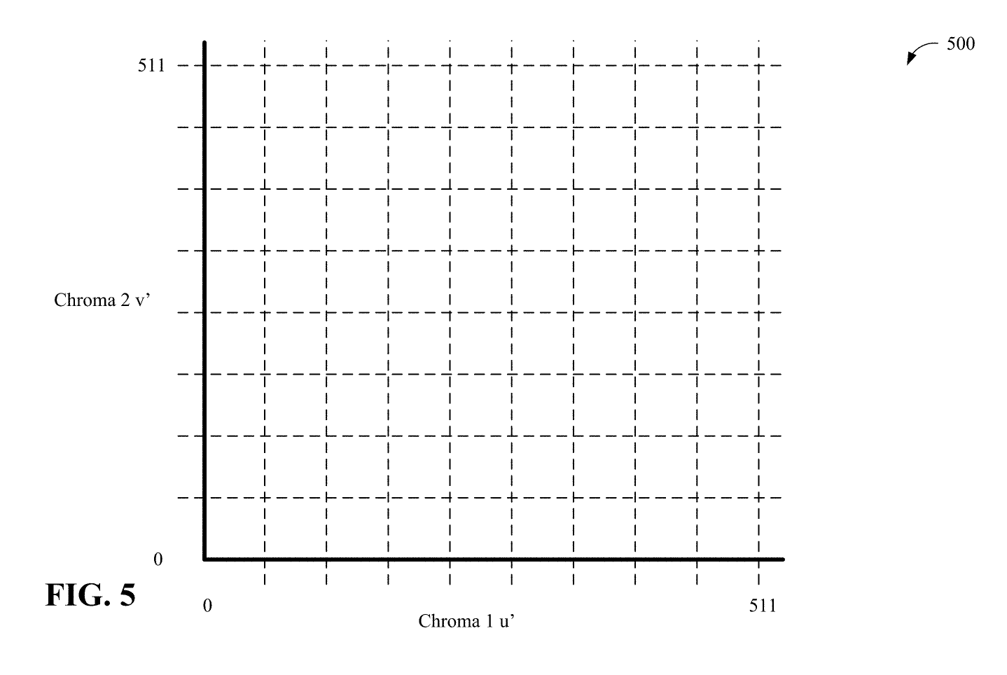

By using 14 bits total to represent or define luminance 404, 18 bits may remain for representing chroma information 406 and 408, while still maintaining an overall size of 32 bits. As a result, 9 bits each may be used to define chroma values U and V (C0-C8 for each of chroma 406 and chroma 408). In this way 512 color values may be available for each of U and V. An example distribution of color values using 9 bits each for U and V is illustrated in FIG. 5.

For L14U9V9 to be a useful format, it needs to be renderable. In other words, L14U9V9 must be usable as a render target format and support alpha blending. On current hardware, L14U9V9 could be used in limited ways by doing “manual encoding and decoding,” but it would be restricted from alpha blending and texture filtering. Stated another way, current hardware is not capable of performing alpha blending and texture filtering on this 32 bit HDR format. In one example, programmable blending in hardware (e.g., of the GPU), could be used to support alpha blending of L14U9V9. For alpha blending, the naive approach would be to decode the color all the way back to RGB, blend as usual, and then re-encode all the way back to LUV. That is an unnecessary amount of math that can be optimized by only decoding to the intermediate, linear number space.

As the chroma component (U and V) is not a linear projection, it cannot, therefore, be linearly interpolated. The solution is to unwind the packing all the way to the output of the 3×3 vector transformation (e.g., to AYB space, as mentioned above). This vector is still linear and can be blended or filtered as if it were RGB. Unfortunately, this incurs one reciprocal per decode (not per channel) as well as one reciprocal per encode. To filter four values (bilinear), four reciprocals may be computed (e.g., a 9-bit lookup). To write it back to memory, one more reciprocal is needed.

The following described the intermediate color space as it applies to linearly blending. The intermediate space is still linear but provides the three terms needed to pack the entire color value into 32-bits.

Intermediate Space: A, Y, B

[A, Y, B′]=Matrix*[R, G, B]

Everything can be blended in this space because the linear transformation is affine which results in yet another linear space. Compressing the three (linear) terms into LUV32 can be performed as follows:

L=PackFloat14(Y)

U=PackUnorm9(A/B)

V=PackUnorm9(A/B)

What makes this compressed color space non-linear and therefore not blendable is the division operation. To uncompress back to the linear space, the division operation needs to be reversed, which requires another division (e.g., a reciprocal).

Y=UnpackFloat14(L)

B=Y/UnpackUnorm9(V)

A=UnpackUnorm9(U)*B

Everything can now be linearly blended again. Notice that only one reciprocal was needed, but deriving B required both L and V channels, and deriving A required all three channels. It is this “cross channel” data sharing that lacks precedent amongst other renderable pixel formats.

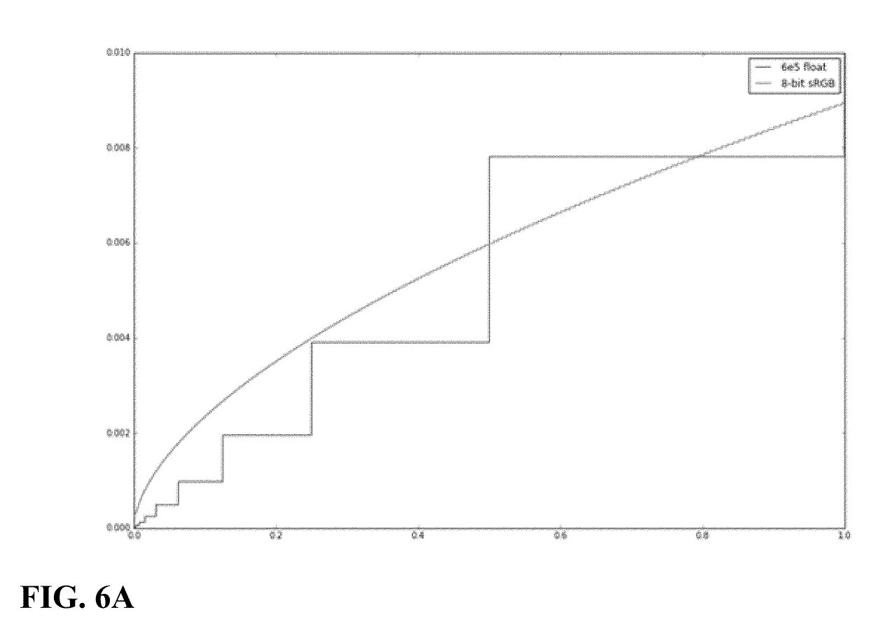

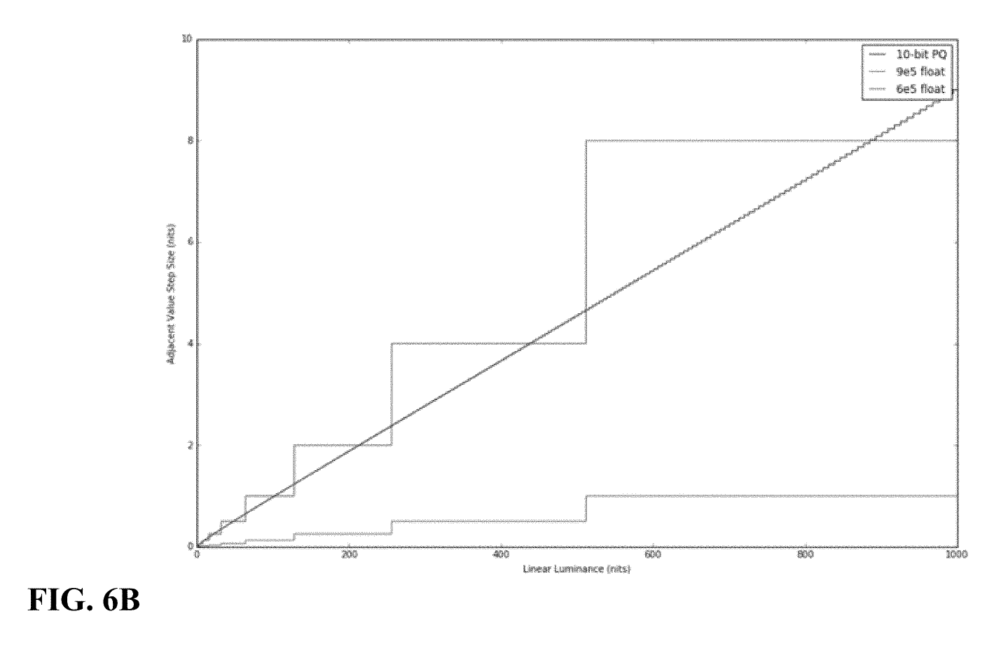

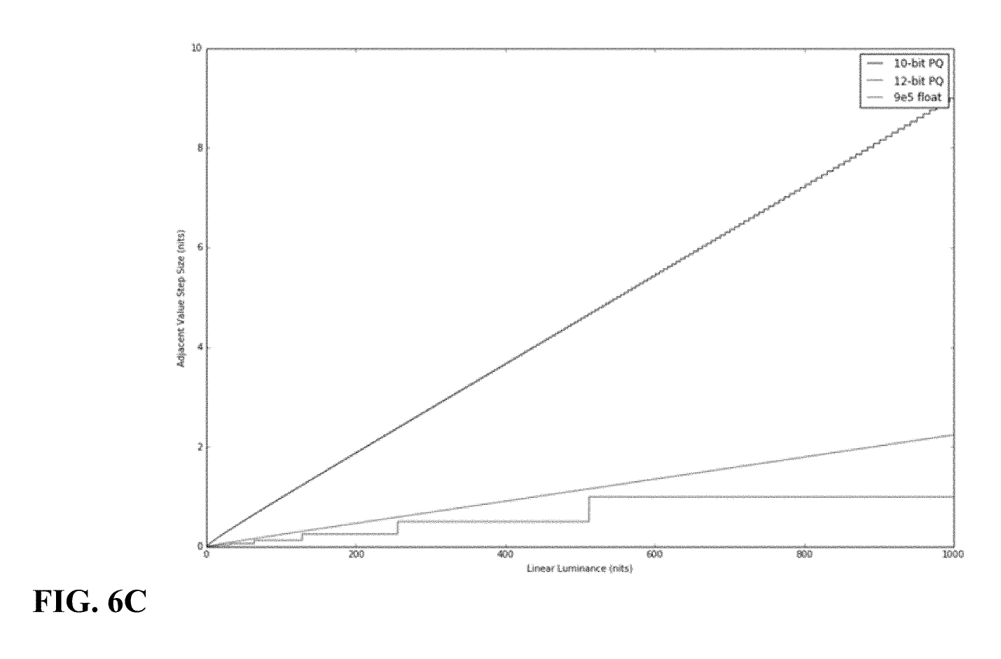

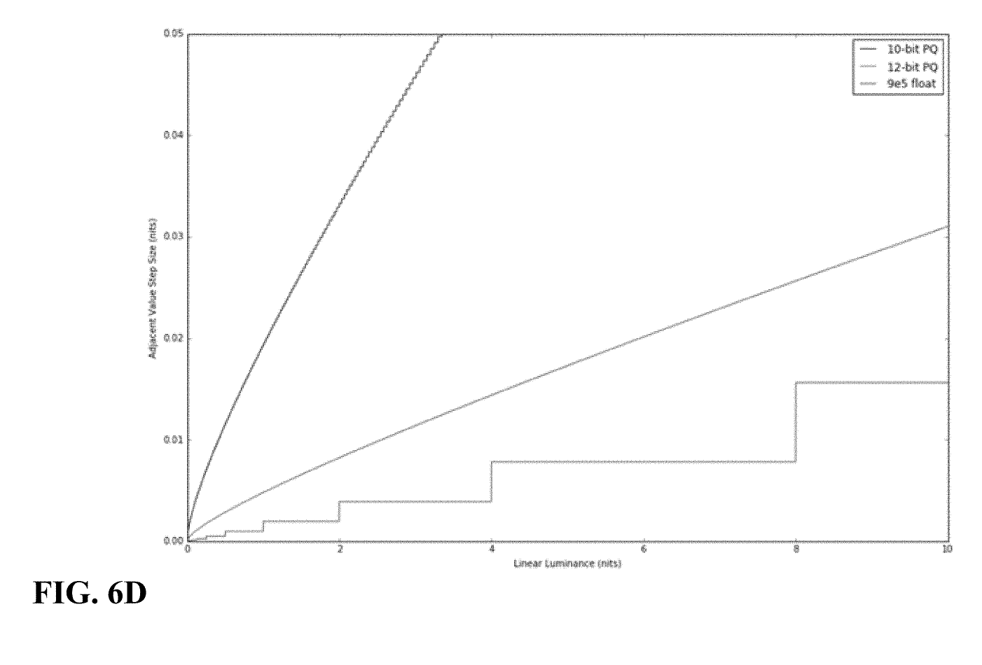

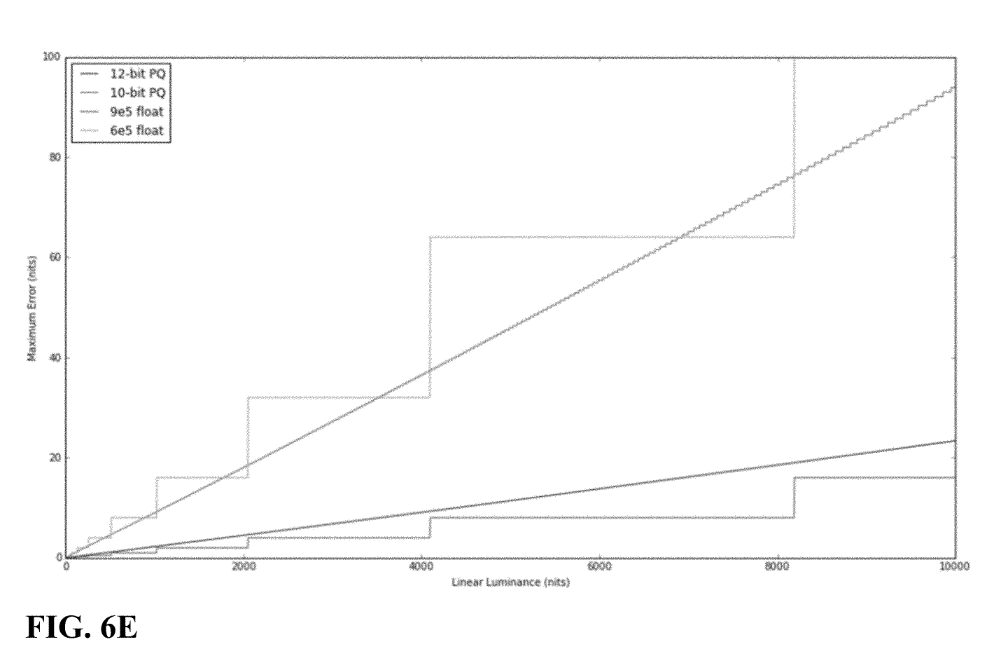

FIGS. 6A, 6B, 6C, 6D and 6E depict graphs of comparisons between different color or pixel formats.
R11G11B10_FLOAT

First observe that with R11G11B10 there is no alpha channel. This immediately raises concerns as it is thought necessary to have an alpha channel to support alpha blending. This is not the case. When rendering a pixel, an alpha value may always be output from a pixel shader, but few algorithms require the destination pixel to have alpha. Typically, a destination alpha is used for deferred composition of two images. An auxiliary 8-bit buffer can be used instead, if this is the goal. The desktop window manager (DWM) needs to know the alpha of a surface for compositing windows (i.e., “flattening layers”), but it can be assumed that windows lacking an alpha channel are fully opaque. By removing the alpha channel, an immediate savings of 16 bits may be realized, but 48-bit formats do not currently exist.

To quantify the precision of a number space, we must estimate the maximum error across the representation. A float with a 6-bit mantissa will have 2⁶ steps between the values 0.5 and 1.0. That is a step size of 2⁻⁷ or 7.8125×10⁻³. When comparing that to encoding the values 0.5 and 1.0 with an 8-bit sRGB ramp, where the step sizes grow with each discrete value, the sRGB step size at 0.5 is approximately 6.0×10⁻³ and rises to 9.0×10⁻³ near 1.0. This comparison is illustrated in FIG. 6A.

8-bit sRGB is used as a comparison because it has been “good enough” for SDR (standard dynamic range) content but can still exhibit banding. So while R11G11B10 has sufficient dynamic range for HDR colors, it's barely as good as 8-bit sRGB for SDR colors and may exhibit banding. It is inferior to 10-bit sRGB, 10-bit PQ, and ultimately 12-bit PQ (which all have static range, i.e., not floating point). Each format encodes values from 0.0 to 1.0 with fixed point numbers but applies a curve to increase precision toward 0.0, where human eyes are most sensitive.
R9G9B9E5_SHAREDEXP

There has existed another HDR color format for a while, but it's been largely ignored for two main reasons: it is not possible to render to this format (or alpha blend with it), and while textures can be created with this format, they are not block compressed, making them much fatter than BC6H-compressed textures.

R9G9B9E5 with a shared exponent is similar to R11G11B10 in that it encodes three floating point channels. However, the difference is that all three channels must share a single exponent value. The trade-off is that 9 bits are available to represent each channel. The exponent may be used to control the brightness of the pixel to the nearest power of 2, and then the color is determined by 27 bits as well as fine-grained adjustments to brightness. However, with this format, there are not three 9e5 floats (which would be 42 bits). A float has an implicit 1.0+ before the mantissa. These three channels are unorm (unsigned normalized numbers between 0 and 1.) They have no implicit 1.0+ and must make that bit explicit (this way, the biggest channel may be indicated). As a result, the biggest channel (which determines the exponent) is effectively an 8e5 float. The precision with an 8e5 float is acceptable, but the other two channels are not even floating point. The largest channel just fixed the decimal point in place, so if their natural exponent is much smaller, their bits get shifted out to the right.

The easiest way to understand this shortcoming is that ignoring its dynamic range, R9G9B9E5 is just three 9-bit UNORM channels, which are stored linearly. For encoding an SDR color, this is inferior to sRGB which uses a curve to increase precision in the blacks. Storing sRGB colors linearly would require about 12 bits per channel. Here, only 9 bits are available. This may be acceptable because dark colors will get a smaller shared exponent and maintain precision, but when one color channel is much brighter than the others, such as a saturated color, then the precision of the smaller channels suffers. The error is determined by the exponent. One solution for this problem is to apply the sRGB ramp to each of the 9-bit unorm channels. This results in precision at least as good as 8-bit sRGB for storing saturated SDR colors, and high dynamic range is still available. Since sRGB is somewhat expensive to compute, and 9-bit look-up tables take up valuable silicon real estate, the sqrt( )could be used to almost the same effect (and note that only a square root estimate to 9 bits is needed).
32 HDR Format

The HDR data structure of FIG. 4 may be compared to 10-bit PQ. 9e5 has high dynamic range, while PQ is for static range. For example with PQ, a scene may be rendered with a virtual camera, which may result in the scene being really dark or really bright. This output can be rescaled or “exposed” to the displayable static range. As a result, 9e5 needs to have as much precision as 10-bit PQ but also orders of magnitude more range. PQ is designed to encode a range of 0-10,000 nits. With a 5-bit exponent float (e5), values almost up to 2¹⁶=65,535 can be encoded. For example, the same values may be encoded linearly with Y=10,000 stored as the value 10000.0h. FIG. 6B illustrates a plot of the step sizes for the two encodings, and the 6e5 float from R11G11B10 encoding for comparison.

As illustrated, 6e5 can have almost double the error as 10-bit PQ. The 9e5 float, which is also referred to herein as float14, is substantially more precise. 9e5 float has the dynamic range to handle pre-exposed HDR values (within the demands of modem video games).

FIGS. 6C and 6D (zoomed in from FIG. 5C) illustrate a comparison between 14 bit float and 12-bit PQ. As illustrated, 14-bit float is superior to the non-linear (and expensive) PQ encoding at 12 bits. Given that this precision can be maintained throughout the entire rendering or graphics pipeline, L14U9V9 could be used in the scan out operation, such that the requirements for HDR12 would be met.

FIG. 6E plots the maximal errors of the aforementioned numerical representations for comparison.

As LUV color is already color space agnostic and encodes all visible colors above and beyond Rec.2020, the described format will support wide color gamuts. This may be accomplished by either authoring and storing all content in a wide gamut, or converting some or all colors to a wider gamut before display. In the scenario that color information has to be transformed with a 3×3 matrix anyway, full adoption of the described 32-bit LUV format for intermediate surfaces (and authored content) would not add any or minimal computational cost.

On top of having high dynamic range and precision for luminance and being able to encode wide gamut colors, there may be additional advantages to keeping luma separated from chroma. There is an ongoing debate as to whether tone mapping should saturate/desaturate colors or should just operate on luminance. Exposure, tone mapping, and even contrast adjustments could all operate on just the luma channel. Color grading, which involves hue shifts and saturation control, could all be 2D operations on chroma. It is common for game engines to use a 3D lookup table for color grading but this requires low-resolution volume textures. Perhaps if luminance does not play a factor in procedural color adjustments, a 2D texture lookup can be used to great effect. Or considering that saturation is just a blending toward or away from the white point, and contrast is a gamma function on luminance, simplistic image controls may be obtained without lookup tables.

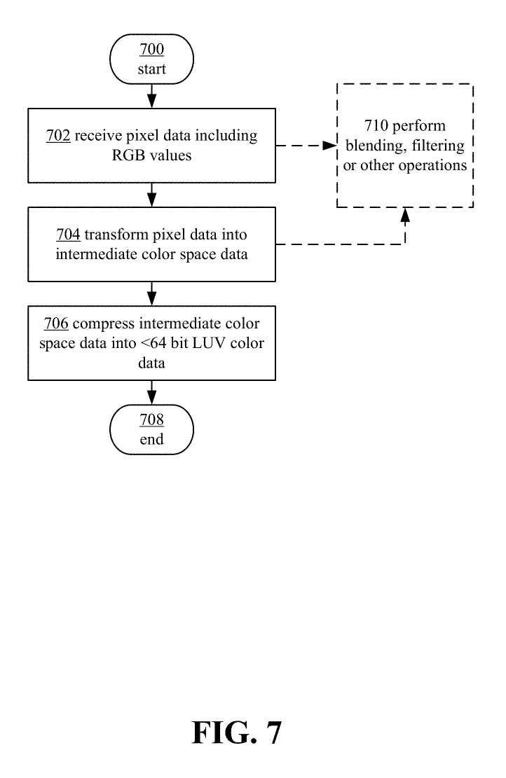

FIG. 7 depicts an example process for encoding pixel data utilizing an intermediate color space. In some aspects, process 700 may be implemented to encode color data into a 32 bit HDR image format or data structure (e.g., L14U9V9). Process 700 may be performed by one or more hardware components of a GPU, such as GPU 108, one or more software components of GPU pipeline 200, software executing on CPU 106, or combinations thereof.

Process 700 may begin at operation 702, in which pixel data, such as in the format of RGB may be received. The pixel data may be in any RGB defined color space, such as sRGB, Rec. 2020, Rec. 709, and others. The pixel data may be received by a GPU or CU with integrated GPU functionality. The GPU may or may not perform the transformation from RGB to the intermediate space with fixed function logic units. For fixed function alpha blending, the GPU must perform the final conversion from the intermediate space to LUV and compress to 32 bits.

Next, at operation 704, the pixel data may be transformed to an intermediate color space, such as AYB space or a variant thereof. In some cases, the intermediate space may be CIE AYB space, or a variant thereof. In the example described above, operation 704 may include converting RGB data into an intermediate space defined by A, Y, B via the relationship:

[A, Y, B]=Matrix*[R, G, B]

Next, at operation 706, the intermediate color space data produced by operation 704 may be or converted into LUV color data, for example m that may include less than 64 bits (e.g., 32 bits as described above). In some cases, operation 706 may include compressing the intermediate color data into 32 bits that define color including a high dynamic range. The 32 bits may be allocated as described above in reference to the data structure 400 of FIG. 4. In other cases, the bits may be allocated in other ways, such as 16 bits for luminance and 8 bits each for u′ and v′, and other configurations. In some cases, operation 706 may include compressing the three (linear) terms A, Y, B into LUV32, such as according to the following:

L=PackFloat14(Y)

U=PackUnorm9(A/B)

V=PackUnorm9(Y/B)

Upon compressing the data into LUV color data, process 700 may end at 708, at which point the data may be communicated from GPU 108 and/or CPU 106 to another computing device, rendered to a display device (in cases where the display device 104 supports the 32 bit HDR color format), stored in memory, either of a computing device 102 or of GPU 108 for later rendering or transmission, etc.

In some aspects, some or all of operation 702, 704, and 706 may be performed in hardware, e.g., by the GPU 108. In other aspects, one or more of operations 702, 704, and 706 may be performed in software, such as by programmable shader instructions. In one example, a user could write RGB values (e.g., with Rec.709 primaries), and the hardware may automatically transform the RGB values to LUV and pack them into a 32 bits format, such as data structure 400. In another example, the transformation may be performed in software, and the packing/unpacking (compression 706) may be performed in hardware (e.g., GPU 108 implementing rendering pipeline 200). This option may use the least silicon and will avoid tying the hardware to a color space that may become obsolete or be deprecated (e.g., Rec.709). However, as the source color space just determines what 3×3 matrix to use to convert to AYB space, process 700, when implemented in hardware, could be modified to support other color spaces. For example, the matrix values may be programmable, but multiplication with the matrix may occur in the fixed function units.

By utilizing process 700 and/or HDR color data structure 400, much better image quality may be produced out of 32-bit formats. This has the potential to save energy (most applicable for power-starved devices), reduce heat, improve performance, etc. This may be especially important on the many size and power-constrained devices such as video game consoles, mobile phones, and wearable devices or other virtual reality or augmented reality devices.

In the 3×3 matrix conversion into the AYB space, V ranges from 0 to 0.62, and U ranges from 0 to 0.59. Precision in the U channel may be increased by reducing the encoded range separately from V. An example of instructions for generating the matrices required to convert common RGB spaces into the intermediate linear space referred to as (A, Y, B) is provided below:

| In [1]: | import numpy as np | | |
|---|---|---|---|
| | def MakeRGBtoXYZMatrix ( Rx, Ry, Gx, Gy, Bx, By, Wx = 0.31271, Wy = 0.32902 ) : | | |
| | M = np.array ( [Rx, Gx, Bx], [Ry, Gy, By], [1-Rx-Ry, 1-Gx-Gy, 1-Bx-By] ] ) | | |
| | return M @ np.diagflat (np.linalg.inv (M) @ np.array ([Wx, Wy, 1-Wx-Wy]) / Wy) | | |
| | def PrintMatrix ( m, name= ‘myMatrix’ ) : | | |
| | print ( ‘ static const float3x3 ’ + name + ‘ [ ] =’ ) | | |
| | print ( ‘ { ’ ) | | |
| | print ( ‘ { : f }, { : f }, { : f }, ’ .format (m[0,0], m[0,1], m[0,2] ) ) | | |
| | print ( ‘ { : f }, { : f }, { : f }, ’ .format (m[1,0], m[1,1], m[1,2] ) ) | | |
| | print ( ‘ { : f }, { : f }, { : f }, ’ .format (m[2,0], m[2,1], m[2,2] ) ) | | |
| | print ( ‘ }; ’ ) | | |
| In [2]: | XYZtoLUV = np.array ( [ 4 / 9 * 0.59 / 0.62,0, 0], | | |
| | [0, 1, 0], | | |
| | [0.59 / 9,0.59 / 9 * 15, 0.59 / 9 * 3] ] ) | | |
| | From2020 = MakeRGBtoXYZMatrix (0.708, 0.292, 0.170, 0.797, 0.131, 0.046) | | |
| | From709 = MakeRGBtoXYZMatrix (0.64, 0.33, 0.30, 0.60, 0.15, 0.06) | | |
| | FromP3 = MakeRGBtoXYZMatrix (0.68, 0.32, 0.265, 0.69, 0.15, 0.06) | | |
| In [3] | From 202 0toLUV = XYZtoLUV @ From2020 | | |
| | PrintMatrix (From2020toLUV, ‘mat2020toLUV’ ) | | |
| | PrintMatrix (np.linalg.inv (From2020toLUV), ‘matLUVto2020’ ) | | |
| | static const float3x3 mat2020toLUV[ ] = | | |
| | { | | |
| | 0.269393, | 0.061165, | 0.071416, |
| | 0.262698, | 0.678009. | 0.059293, |
| | 0.300076, | 0.681710, | 0.278003 |
| | }; | | |
| | static const float3x3 matLUVto2020 [ ] = | | |
| | { | | |
| | 4.258579, | 0.911167, | -1.288312, |
| | -1.588716, | 1.537614, | 0.080178, |
| | -0.700901, | -4753993, | 4.791068 |
| | }; | | |
| In [4] | From709toLUV = XYZtoLUV @ From709 | | |
| | PrintMatrix (From709toLUV, ‘mat709toLUV’ ) | | |
| | PrintMatrix (np.linalg.inv (From709toLUV), ‘matLUVto709’ ) | | |
| | static const float3x3 mat709toLUV[ ] = | | |
| | { | | |
| | 0.174414, | 0.151239, | 0.076320, |
| | 0.212637, | 0.715183. | 0.072180, |
| | 0.239929, | 0.750147, | 0.269713 |
| | }; | | |
| | static const float3x3 matLUVto709 [ ] = | | |
| | { | | |
| | 8.056027, | 0.955680, | -2.535335, |
| | -2.324391, | 1.668159, | 0.211293, |
| | -0.701623, | -5.489756, | 5.375334 |
| | }; | | |
| In [5] | From709to2020 = np.linalg.inv (From2020) @ From709 | | |
| | PrintMatrix (From709to2020, ‘mat709to2020’ ) | | |
| | PrintMatrix (np.linalg.inv (From709to2020), ‘mat2020to709’ ) | | |
| | static const float3x3 mat709to2020[ ] = | | |
| | { | | |
| | 0.627402, | 0.329292, | 0.043306, |
| | 0.069095, | 0.919544, | 0.011360, |
| | 0.016394, | 0.088028, | 0.895578 |
| | }; | | |
| | static const float3x3 mat2020to709 [ ] = | | |
| | { | | |
| | 1.660496, | -0.587656, | -0.072840, |
| | -0.124547, | 1.132895, | 0.008348, |
| | -0.018154, | -0.100597, | 1.118751 |
| | }; | | |
| | Rec. 709 to LUV | | |
| | { | | |
| | 0.183283, | 0.158930, | 0.080200, |
| | 0.212637, | 0.715183, | 0.072180, |
| | 0.252129, | 0.788291, | 0.283428 |

LUV to Rec. 709

| { | | |
|---|---|---|
| 7.666219, | 0.955680, | -2412657, |
| -2.211920, | 1.668159, | 0.201069, |
| -0.667673, | -5.489756, | 5.115237 |

}

In some aspects of process 700, one or more blending, filtering, other operation may be performed on the pixel data, at operation 710 (optional). In some cases, operation 710 may be performed on the RGB values, for example, following operation 702, or may be performed on intermediate color space data, following operation 704.

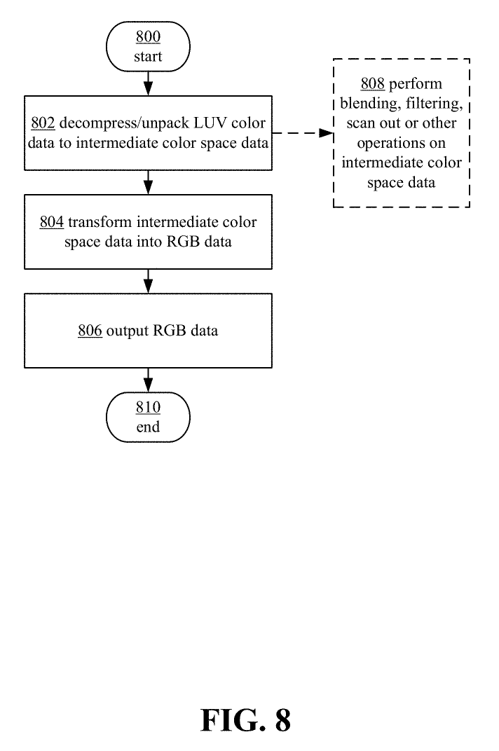

FIG. 8 depicts an example process for decoding pixel data utilizing an intermediate color space. In some aspects, process 800 may be implemented to decode color data in a 32 bit HDR image format or data structure (e.g., L14U9V9). Process 800 may be performed by one or more hardware components of a GPU, such as GPU 108, one or more software components of graphics pipeline 200, software executing on CPU 106, or combinations thereof. Process 800 may be implemented as the inverse of process 700 described above.

Process 800 may begin at operation 802, in which LUV data (e.g., in 32 bit HDR format 400) may be decompressed or unpacked into an intermediate color space data. To uncompress the LUV data back to the linear space, the division operation needs to be inverted, which requires another reciprocal. Operation 802 may include unpacking each value of the intermediate space as follows:

Y=UnpackFloat14(L)

B=Y/UnpackUnorm9(V)

A=UnpackUnorm9(U)*B

In some aspects, once the LUV data has been decompressed to AYB data, the color information may be linearly blended again. Notice that only one reciprocal was needed, but deriving B required both L and V channels, and deriving A required all three channels. In some aspects of process 800, operation 808 may be next performed (optional), in which one or more operations, such as filtering, blending, and upscaling may be performed on the intermediate color space data. In this way, computing resources, memory resources, and/or time may be saved when compared to decoding the color information all the way to RGB information (e.g., performing one or more of operations 804 or 806) to perform these operation.

In some cases, operations that may be performed on the intermediate color space data (e.g., linear color data) at operation 808, may include reading, writing, blending (which may be characterized as a read, modify, write operations), filtered sample operation (e.g., gathering 4 adjacent pixels, decoding them individually, and blending them together), and/or scan out or rasterizing to a 2D array. In some aspects, one or more of these operations may be performed in hardware (e.g., GPU 108) to further increase the efficiencies provided by the 32 bit HDR color format.

An example of instructions for converting and blending the 32 bit HDR color format is provided below:

| In [1]: | import numpy as np | |
|---|---|---|
| | import matlotlib.pyplo as plt | |
| | Imatplotlib inline | |
| | import math | |
| In [2]: | def | MakeRGBtoXYZMatrix( Rx, Ry, Gx, Gy, Br, By, Wx = 0.31271, Wy = 0.32902 ); |
| | | MakeXYZ = lamda x, y: np array((x, y, (1 − x − y))) |
| | | M = np.matrix(np.column_stack( [MakeXYZ(Rx, Ry), MakeXYZ(Gx, Gy), MakeXYZ(Bx, By)))) |
| | | return M = np.diagflat(M, I * np.matrix(MakeXYZ(Wx, Wy) / T) |
| | XYZto LUV = np.matrix([[4.0 / 9.0, 0, 0], [0, 1, 0], [0.62 / 9.0, 0.62 / 9.0 * 15, 0.02 / 9.0 * 3] | |
| | From709toXYZ = MakeRBGtoXYZMatrix(0.64, 0.33, 0.30, 0.60, 0.15, 0.06) | |
| | From709toLUV = XYZtoLUV 0 From709toXYZ | |
| | FromLUVto709 = From709toLUV, I | |
| | def | saturate( x ): |
| | | return np.where(np.less(x, 0.0), 0.0, np.where(np.greater(x, 1.0), 1.0, x)) |
| | def | ReduceFloatPrecision( f, mantissa_bits, exponent_bits, specials=True ): |
| | | Exp = math.floor(math.log2(f)) |
| | | min_exp = 2 − 2 ** (exponent_bits − 1) |
| | | max_exp = 1 − min.exp |
| | | if not specials: |
| | | max_exp <= 1 |
| | | Scale = 2.0 ** mantissa_bits |
| | | if f < 2.0 ** min_exp: |
| | | f *= 2.0 ** min_exp |
| | | f = round(f * Scale) / Scale |
| | | return f * 2.0 ** min_exp |
| | | else: |
| | | f = (2.0 ** −Exp) * f − 1.0 |
| | | f = round(f * Scale) / Scale |
| | | return (f + 1.0) * 2.0 ** Exp |
| | def | DecompressLUV( luv ): |
| | | Y = luv[0] |
| | | XYZp = Y / luv[2] |
| | | Xp = luv[1] + XYZp |
| | | return np.array([Xp, Y, XYZp], dtype=float) |
| | def | QuantizeLUV( luv ); |
| | | luv[0] = ReduceFloatPrecision(luv[0], 0, 5) |
| | | luv[1:] = np.round(luv[1:] * 611.0) / 611.0 |
| | | return luv |
| | def | CompressLUV( Xp_Y_XYZp, quantize=True ); |
| | | L = Xp_Y_XYZp[1] |
| | | U = Xp_Y_XYZp[0] / Xp_Y_XYZp[2] |
| | | V = Xp_Y_XYZp[1] / Xp_Y_XYZp[2] |
| | | luv = np.array([L, U, V], dtype=float) |
| | | if quantive: |
| | | luv = QuantizeLUV(luv) |
| | | return luv |
| | def | RGBtoLuv( rgb, quantive=True ): |
| | | return CompressLUV(From709toLUV, A @ rgb, quantize |
| | def | LUVtoRGB( luv ): |
| | | return FromLuvto709, A @ DecompressLUV(luv) |
| | def | LerpRGB( rgb1, rgb2, t): |
| | | return rgb1 = (1-t) + rgb2 * t |
| | def | LerpLUV( luv1, luv2, t ): |
| | | return CompressLUV(LerpRGB(DecompressLUV(luv1), DecompressLUV(luv2), t)) |
| | def | CompareRGB(rgb1, rgb2): |
| | | print(‘1Error’, np.abs(rgb1 − rgb2) / rgb1) |
| | def | CompareLUV(luv1, luv2): |
| | | Cdiff = luv1[1:] − luv2[1:] |
| | | L1 = luv1[0] |
| | | L2 = luv2[0] |
| | | print(‘Difference in C’, np.sqrt(Cdiff @ Cdiff.T)) |
| | | print(‘Difference in L’, abs(L1 − L2) / L1) |
| | def | TestLUVConversion( rgb1 ): |
| | | rgb2 = LUVtoRGB(RGBtoLUV(rgb1)) |
| | | print(‘Before’, rgb1) |
| | | print(‘After’, rgb2) |
| | | CompareRGB(rgb1, rgb2) |
| | def | TestLerp( rgb1, rgb2, t ): |
| | | RGBResult = RGBtoLUV(LerpRGB(rgb1, rgb2, t), False) |
| | | LUVResult = LerpLUV(RGBtoLUV(rgb1), RGBtoLUV(rgb2), t) |
| | | CompareLUV(RGBResult, LUVResult) |
| | def | MakeRGB( r, g, b ): |
| | | r = ReduceFloatPrecision(r, 10, 5) |
| | | g = ReduceFloatPrecision(g, 10, 5) |
| | | b = ReduceFloatPrecision(b, 10, 5) |
| | | return np.array([r, g, b], dtype=float) |

| | |
|---|---|
| In [3]: | a = MakeRGB(3.56, 1.22, 9.1) / 9.12 |
| | b = MakeRGB(2.01, 7.32, 0.1722) * 2.283 |
| | TestLUVConversion(a) |
| | TestLUVConversion(b) |
| | TestLerp(a, b, 0.41234) |

```
  Before [ 0.39041084 0.13374195 0.99797834]
  After [ 0.38674405 0.13440115 0.99931626]
  ZError [ 0.00939214 0.00492888 0.00134063]
  Before [ 4.58829492 16.71227344 0.39322668]
  After 4.61309598 16.69405821 0.45586742]
  ZError 0.00540529 0.00108993 0.1592993 ]
  Difference in C 0.00143229415608
  Difference in L 0.000443889620153
```

Next, at operation 804, the intermediate color space data may be transformed to RGB color data, according to the following relationship, as described above:

[R, G, B]=Matrix⁻¹*[A, Y, B]

The RGB color information may then be output at operation 810, at which point process 800 may end.

In some aspects, some or all of operations 802, 804, 806, and 808 may be performed in hardware, e.g., by the GPU 108. In other aspects, one or more of operations 802, 804, 806, and 808 may be performed in software, such as associated with CPU 106. In some aspects, operations of process 800 may be allocated to hardware and/or software to match process 700, or may be different.

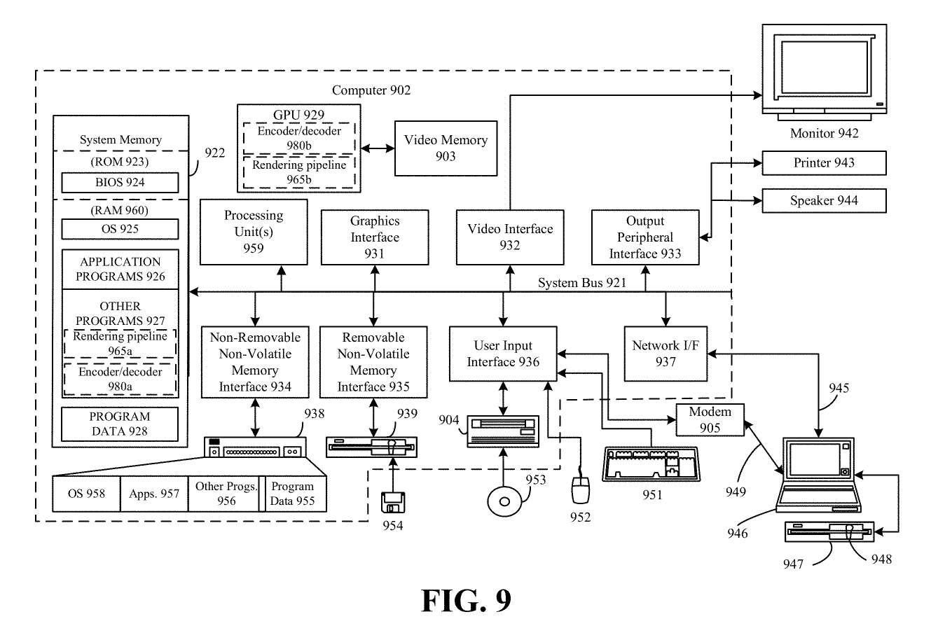

The techniques described above may be implemented on one or more computing devices or environments, as described in more detail below. FIG. 9 depicts another example general purpose computing environment, for example, which includes a GPU 929 in communication with video or image memory 903, in which some of the techniques described herein may be embodied. The computing system environment 902 is only one example of a suitable computing environment and is not intended to suggest any limitation as to the scope of use or functionality of the presently disclosed subject matter. Neither should the computing environment 902 be interpreted as having any dependency or requirement relating to any one or combination of components illustrated in the example operating environment 902. In some embodiments the various depicted computing elements may include circuitry configured to instantiate specific aspects of the present disclosure. For example, the term circuitry used in the disclosure can include specialized hardware components configured to perform function(s) by firmware or switches. In other example embodiments, the term circuitry can include a general purpose processing unit, memory, etc., configured by software instructions that embody logic operable to perform function(s). In example embodiments where circuitry includes a combination of hardware and software, an implementer may write source code embodying logic and the source code can be compiled into machine readable code that can be processed by the general purpose processing unit. Since one skilled in the art can appreciate that the state of the art has evolved to a point where there is little difference between hardware, software, or a combination of hardware/software, the selection of hardware versus software to effectuate specific functions is a design choice left to an implementer. More specifically, one of skill in the art can appreciate that a software process can be transformed into an equivalent hardware structure, and a hardware structure can itself be transformed into an equivalent software process. Thus, the selection of a hardware implementation versus a software implementation is one of design choice and left to the implementer.

Computer 902, which may include any of a mobile device or smart phone, tablet, laptop, desktop computer, or collection of networked devices, cloud computing resources, etc., typically includes a variety of computer-readable media. Computer-readable media can be any available media that can be accessed by computer 902 and includes both volatile and nonvolatile media, removable and non-removable media. The system memory 922 includes computer-readable storage media in the form of volatile and/or nonvolatile memory such as read only memory (ROM) 923 and random access memory (RAM) 960. A basic input/output system 924 (BIOS), containing the basic routines that help to transfer information between elements within computer 902, such as during start-up, is typically stored in ROM 923. RAM 960 typically contains data and/or program modules that are immediately accessible to and/or presently being operated on by processing unit 959. By way of example, and not limitation, FIG. 9 illustrates operating system 925, application programs 926, other program modules 927 including a rendering pipeline 965a, and program data 928. In some aspects, rendering pipeline 965a may be in part or wholly implemented in GPU 929 as rendering pipeline 965b, as described above.

The computer 902 may also include other removable/non-removable, volatile/nonvolatile computer storage media. By way of example only, FIG. 9 illustrates a hard disk drive 938 that reads from or writes to non-removable, nonvolatile magnetic media, a magnetic disk drive 939 that reads from or writes to a removable, nonvolatile magnetic disk 954, and an optical disk drive 904 that reads from or writes to a removable, nonvolatile optical disk 953 such as a CD ROM or other optical media. Other removable/non-removable, volatile/nonvolatile computer storage media that can be used in the example operating environment include, but are not limited to, magnetic tape cassettes, flash memory cards, digital versatile disks, digital video tape, solid state RAM, solid state ROM, and the like. The hard disk drive 938 is typically connected to the system bus 921 through a non-removable memory interface such as interface 934, and magnetic disk drive 939 and optical disk drive 904 are typically connected to the system bus 921 by a removable memory interface, such as interface 935 or 936.

The drives and their associated computer storage media discussed above and illustrated in FIG. 9, provide storage of computer-readable instructions, data structures, program modules and other data for the computer 902. In FIG. 9, for example, hard disk drive 938 is illustrated as storing operating system 958, application programs 957, other program modules 956, and program data 955. Note that these components can either be the same as or different from operating system 925, application programs 926, other program modules 927, and program data 928. Operating system 958, application programs 957, other program modules 956, and program data 955 are given different numbers here to illustrate that, at a minimum, they are different copies. A user may enter commands and information into the computer 902 through input devices such as a keyboard 951 and pointing device 952, commonly referred to as a mouse, trackball or touch pad. Other input devices (not shown) may include a microphone, joystick, game pad, satellite dish, scanner, retinal scanner, or the like. These and other input devices are often connected to the processing unit 959 through a user input interface 936 that is coupled to the system bus 921, but may be connected by other interface and bus structures, such as a parallel port, game port or a universal serial bus (USB). A monitor 942 or other type of display device is also connected to the system bus 921 via an interface, such as a video interface 932. In addition to the monitor, computers may also include other peripheral output devices such as speakers 944 and printer 943, which may be connected through an output peripheral interface 933.

The computer 902 may operate in a networked environment using logical connections to one or more remote computers, such as a remote computer 946. The remote computer 946 may be a personal computer, a server, a router, a network PC, a peer device or other common network node, and typically includes many or all of the elements described above relative to the computer 902, although only a memory storage device 947 has been illustrated in FIG. 9. The logical connections depicted in FIG. 9 include a local area network (LAN) 945 and a wide area network (WAN) 949, but may also include other networks. Such networking environments are commonplace in offices, enterprise-wide computer networks, intranets, the Internet, and cloud computing resources.

When used in a LAN networking environment, the computer 902 is connected to the LAN 945 through a network interface or adapter 937. When used in a WAN networking environment, the computer 902 typically includes a modem 905 or other means for establishing communications over the WAN 949, such as the Internet. The modem 905, which may be internal or external, may be connected to the system bus 921 via the user input interface 936, or other appropriate mechanism. In a networked environment, program modules depicted relative to the computer 902, or portions thereof, may be stored in the remote memory storage device. By way of example, and not limitation, FIG. 9 illustrates remote application programs 948 as residing on memory device 947. It will be appreciated that the network connections shown are example and other means of establishing a communications link between the computers may be used.

In some aspects, other programs 927 may include a rendering pipeline 965a that may include the functionality as described above. In some cases, a rendering pipeline 965b may be instead implemented in GPU 929. In some cases, GPU 929 may also include a custom encoder/decoder 980b, which may encode and decode 32 bit HDR color data, such as data structure 400, via processes 700 and 800, as described above. In some aspects, encoder/decoder 980a may be implemented, in part or wholly, in software, associated with other programs 927.

Each of the processes, methods and algorithms described in the preceding sections may be embodied in, and fully or partially automated by, code modules executed by one or more computers or computer processors. The code modules may be stored on any type of non-transitory computer-readable medium or computer storage device, such as hard drives, solid state memory, optical disc and/or the like. The processes and algorithms may be implemented partially or wholly in application-specific circuitry. The results of the disclosed processes and process steps may be stored, persistently or otherwise, in any type of non-transitory computer storage such as, e.g., volatile or non-volatile storage. The various features and processes described above may be used independently of one another, or may be combined in various ways. All possible combinations and subcombinations are intended to fall within the scope of this disclosure. In addition, certain methods or process blocks may be omitted in some implementations. The methods and processes described herein are also not limited to any particular sequence, and the blocks or states relating thereto can be performed in other sequences that are appropriate. For example, described blocks or states may be performed in an order other than that specifically disclosed, or multiple blocks or states may be combined in a single block or state. The example blocks or states may be performed in serial, in parallel or in some other manner. Blocks or states may be added to or removed from the disclosed example embodiments. The example systems and components described herein may be configured differently than described. For example, elements may be added to, removed from or rearranged compared to the disclosed example embodiments.

It will also be appreciated that various items are illustrated as being stored in memory or on storage while being used, and that these items or portions thereof may be transferred between memory and other storage devices for purposes of memory management and data integrity. Alternatively, in other embodiments some or all of the software modules and/or systems may execute in memory on another device and communicate with the illustrated computing systems via inter-computer communication. Furthermore, in some embodiments, some or all of the systems and/or modules may be implemented or provided in other ways, such as at least partially in firmware and/or hardware, including, but not limited to, one or more application-specific integrated circuits (ASICs), standard integrated circuits, controllers (e.g., by executing appropriate instructions, and including microcontrollers and/or embedded controllers), field-programmable gate arrays (FPGAs), complex programmable logic devices (CPLDs), etc. Some or all of the modules, systems and data structures may also be stored (e.g., as software instructions or structured data) on a computer-readable medium, such as a hard disk, a memory, a network or a portable media article to be read by an appropriate drive or via an appropriate connection. For purposes of this specification and the claims, the phrase “computer-readable storage medium” and variations thereof, does not include waves, signals, and/or other transitory and/or intangible communication media. The systems, modules and data structures may also be transmitted as generated data signals (e.g., as part of a carrier wave or other analog or digital propagated signal) on a variety of computer-readable transmission media, including wireless-based and wired/cable-based media, and may take a variety of forms (e.g., as part of a single or multiplexed analog signal, or as multiple discrete digital packets or frames). Such computer program products may also take other forms in other embodiments. Accordingly, the present disclosure may be practiced with other computer system configurations.

Conditional language used herein, such as, among others, “can,” “could,” “might,” “may,” “e.g.” and the like, unless specifically stated otherwise, or otherwise understood within the context as used, is generally intended to convey that certain embodiments include, while other embodiments do not include, certain features, elements, and/or steps. Thus, such conditional language is not generally intended to imply that features, elements and/or steps are in any way required for one or more embodiments or that one or more embodiments necessarily include logic for deciding, with or without author input or prompting, whether these features, elements and/or steps are included or are to be performed in any particular embodiment. The terms “comprising,” “including,” “having” and the like are synonymous and are used inclusively, in an open-ended fashion, and do not exclude additional elements, features, acts, operations and so forth. Also, the term “or” is used in its inclusive sense (and not in its exclusive sense) so that when used, for example, to connect a list of elements, the term “or” means one, some or all of the elements in the list.

While certain example embodiments have been described, these embodiments have been presented by way of example only and are not intended to limit the scope of the disclosure. Thus, nothing in the foregoing description is intended to imply that any particular feature, characteristic, step, module or block is necessary or indispensable. Indeed, the novel methods and systems described herein may be embodied in a variety of other forms; furthermore, various omissions, substitutions and changes in the form of the methods and systems described herein may be made without departing from the spirit of the disclosure. The accompanying claims and their equivalents are intended to cover such forms or modifications as would fall within the scope and spirit of certain of the disclosure.

What is claimed is:

1. A method for encoding pixel data, the method comprising:
receiving pixel data comprising a red, green, and blue (RGB) value;
transforming the received pixel data to an intermediate color space data; and
compressing the intermediate color space data into less than 64-bits.

2. The method of claim 1, wherein the intermediate color space data comprises transformed CIE AYB space data or modified AYB space data.

3. The method of claim 2, wherein the transformed CIE AYB space data comprises data defined by [A, Y, B].

4. The method of claim 1, wherein compressing the intermediate color space data into less than 64-bits comprises converting the intermediate color space data into LUV space data, wherein the LUV space data comprises one luminance value (L) and two chrominance values (UV).

5. The method of claim 4, wherein compressing the intermediate color space data into less than 64 bits comprises compressing the LUV color space data into 32-bits.

6. The method of claim 5, wherein the 32-bits comprise 14 bits associated with the luminance value, and 9-bits each for the two chrominance values.

7. The method of claim 6, wherein the 14-bits associated with the luminance value comprises a floating point number and each of the 9-bit chrominance values comprises a fixed point number.

8. The method of claim 6, wherein the 14-bits associated with the luminance value are compressed from 16-bits, wherein compression comprises at least one of rounding off a least significant bit of a mantissa associated with the luminance value or dropping a sign bit associated with the luminance value.

9. The method of claim 1, wherein at least one of transforming the received pixel data to the intermediate color space data or compressing the intermediate color space data into less than 64-bits is performed by one or more hardware components associated with a graphics processing unit (GPU).

10. A method for decoding color data, the method comprising:
unpacking LUV color data to intermediate color space data, wherein the unpacking comprises preforming at least one non-linear operation;
transforming the intermediate color space data into RGB color values; and
outputting the RGB color values.

11. The method of claim 10, wherein the intermediate color space data comprises modified AYB space data or transformed CIE AYB space data.

12. The method of claim 10, wherein the transformed CIE AYB space data comprises data defined by [A, Y, B].

13. The method of claim 10, wherein the LUV color data comprises 32-bits, wherein 14-bits are associated with a luminance value (L), and 9-bits each for two chrominance values (UV).

14. The method of claim 13, wherein the 14-bits associated with the luminance value comprises a floating point number and each of the 9-bit chrominance values comprises a fixed point number.

15. The method of claim 14, wherein the 14-bits associated with the luminance value are compressed from 16-bits, wherein the compression comprises at least one of rounding off a least significant bit of a mantissa associated with the luminance value or dropping a sign bit associated with the luminance value.

16. A method for modifying pixel data, the method comprising:
receiving compressed pixel data, wherein the compressed pixel data is not linearly related to RGB color data;
converting the compressed pixel data to intermediate color space data, wherein the intermediate color space data is linearly related to and combinable with the RGB color data;
modifying at least one value of the intermediate color space data to produce modified intermediate color space data; and
performing at least one of rendering the modified intermediate color space data, storing the modified intermediate color space data in memory, or compressing the modified intermediate color space data into the compressed pixel data.

17. The method of claim 16, wherein at least one of receiving the compressed pixel data, converting the compressed pixel data to the intermediate color space data, or modifying the at least one value of the intermediate color space data to produce the modified intermediate color space data is performed by a GPU or programmed into hardware.

18. The method of claim 16, wherein modifying at least one value of the intermediate color space data to produce modified intermediate color space data comprises at least one of blending the at least one value of the intermediate color space data or filtering the at least one value of the intermediate color space data.

19. The method of claim 16, wherein the compressed pixel data comprises 32-bit HDR color data.

20. The method of claim 16, wherein the intermediate color space data comprises modified AYB space data.
